(19) United States
(12) Patent Application Publication
(10) Pub. No.: US 2026/0255989 A1
(43) Pub. Date: Aug. 27, 2026

(54) STACKABLE FLIP CHIP PACKAGES

(71) Applicant: Sandisk Technologies, Inc., Milpitas, CA (US)

(72) Inventors: Choong Keat Loh, Georgetown (MY); Weng Khoon Mong, Bayan Lepas (MY); Huirong Zhang, Shanghai (CN); Yaqun Zhang, Shanghai (CN)

(21) Appl. No.: 19/060,319

(22) Filed: Feb. 21, 2025

(51) Int. Cl. H01L 23/538; H01L 23/00; H01L 23/31; H01L 23/498; H01L 25/16; H10B 80/00

(52) U.S. Cl. CPC H10W 70/611; H10B 80/00; H10W 90/00; H10W 90/401; H10W 90/701; H10W 74/141; H10W 90/724

(57) ABSTRACT

Examples described herein provide stackable flip chip packages. In one example, a memory package includes a first flip chip package comprising a first memory die and a metal pad. The first flip chip package may also include a molded support at least partially surrounding the first memory die. The first memory die and the metal pad may be situated on opposing sides of a redistribution layer. The package also includes a second flip chip package vertically stacked on the first flip chip package, the second flip chip package including a second memory die and an interconnect configured to contact the metal pad. The interconnect may protrude from a redistribution layer of the second flip chip package. The first flip chip package may be coupled to a printed circuit board of a solid state drive.

### BACKGROUND

The present disclosure relates to storage devices. More particularly, the present disclosure relates to stackable flip chip memory dies.

The capacity and speed of memory arrangements in data storage devices, such as solid state drives (SSDs), is continually improving as technology advances. Demand for higher processing speeds requires increased throughput of memory arrangements. As such, manufacturers of storage devices seek to increase both storage capacity and data throughput for their devices. While it is desirable to increase storage capacity of memory arrangements, increasing the size of the packaged memory package may be undesirable. Further, such improvements are nearly always sought to be implemented at a reduced cost.

### SUMMARY

Printed circuit boards (PCBs) for SSDs have limited space for memory dies (e.g., NAND dies). As one example, the PCB footprint for a M.2 2280 SSD allows for a maximum of eight flip chip NAND dies populated on the top side of the PCB for up to 1 terabyte (TB) of storage capacity.

For storage beyond 1 TB (for example, 2 TB), a second set of flip chip NAND dies may be mounted onto the bottom side (e.g., an opposing side) of the PCB. While use of the bottom side of the PCB provides for additional storage space, use of the bottom side of the PCB also presents challenges in drive handling during assembly and testing. Additionally, to accommodate for the use of both sides of the PCB, additional PCB layers may be required for routing on both sides.

Examples described herein provide a package (e.g., a memory package, an SSD package) using stacked flip chip memory dies. For example, two flip chip dies may be stacked. The stacked flip chip memory dies are then placed adjacent to each other on a single side of the SSD PCB. Stacking the flip chip memory dies provides for an increased storage capacity while utilizing the same PCB footprint as current single-sided SSD PCB designs. Stacking the flip chip memory dies also eliminates the need for additional PCB layers.

The disclosure provides a package including a first flip chip package and a second flip chip package vertically stacked on the first flip chip package. The first flip chip package includes a first memory die, a metal pad, and a redistribution layer. The first memory die is connected to a first side of the redistribution layer and the metal pad is integrated into a second side of the redistribution layer. The second flip chip package includes a second memory die and an interconnect configured to contact the metal die. A center of the first memory die is aligned with a center of the second memory die.

The disclosure also provides a package including a first vertically stacked package and a second vertically stacked package. The first vertically stacked package includes a first memory die electrically and physically coupled to a second memory die, and a first sidewall surrounding at least a portion of the first memory die. The second vertically stacked package includes a third memory die electrically and physically coupled to a fourth memory die and a second sidewall surrounding at least a portion of the third memory die. The first sidewall contacts the second sidewall.

The disclosure also provides a package including a first stacked package and a second stacked package coupled to a top portion of the first stacked package. The first stacked package includes a first memory die electrically and physically coupled to a second memory die. The second stacked package includes a third memory die electrically and physically coupled to a fourth memory die. The first memory die, the second memory die, the third memory die, and the fourth memory die are vertically aligned on a same axis.

In this manner, various aspects of the disclosure provide for improvements in at least the technical fields of packages, such as memory packages, and their design and architecture. The foregoing summary is intended solely to give a general idea of various aspects of the disclosure, and does not limit the scope of the disclosure in any way. Other aspects of the disclosure will become apparent by consideration of the detailed description, the claims, the Abstract, and the accompanying drawings.

### BRIEF DESCRIPTION OF THE DRAWINGS

FIG. 1 is a block diagram illustrating a data storage system, according to embodiments described herein.

FIG. 2 is a diagram illustrating a PCB footprint of a single-sided M.2 2280 SSD PCB, according to embodiments described herein.

FIG. 3A is a diagram illustrating a first side of a PCB footprint of a two-sided M.2 2280 SSD PCB, according to embodiments described herein.

FIG. 3B is a diagram illustrating a second side of a PCB footprint of a two-sided M.2 2280 SSD PCB, according to embodiments described herein.

FIG. 4 is a diagram illustrating a first example of a first package, according to embodiments described herein.

FIG. 5 is a diagram illustrating a second example of the first package, according to embodiments described herein.

FIG. 6 is a diagram illustrating an example of a second package, according to embodiments described herein.

FIG. 7A is a diagram illustrating an example of a stacked package including the first package of FIG. 4 and the second package of FIG. 6, according to embodiments described herein.

FIG. 7B is a bottom view of the stacked package of FIG. 7A, according to embodiments described herein.

FIG. 8A is a diagram illustrating a cross-sectional view of a portion of a SSD PCB architecture including the stacked packages of FIGS. 7A and 7B, according to embodiments described herein.

FIG. 8B is a bottom view of the SSD PCB architecture of FIG. 8A, according to embodiments described herein.

FIG. 8C is a diagram illustrating a plan view of the SSD architecture of FIG. 8A.

FIG. 8D is a diagram illustrating a bottom view of the SSD architecture of FIG. 8A.

FIG. 9 is a diagram illustrating a second example of a SSD architecture including the stacked packages of FIGS. 7A and 7B, according to embodiments described herein.

FIG. 10 is a diagram illustrating a cross-sectional view of a FC memory die tower, according to embodiments described herein.

### DETAILED DESCRIPTION

Before any embodiments of the disclosure are explained in detail, it is to be understood that the disclosure is not limited in its application to the details of construction and the arrangement of components set forth in the following description or illustrated in the following drawings. The disclosure is capable of other embodiments and of being practiced or of being carried out in various ways. It also will be understood by those of skill in the art that the drawings are not to scale, where some features are exaggerated in order to highlight such features.

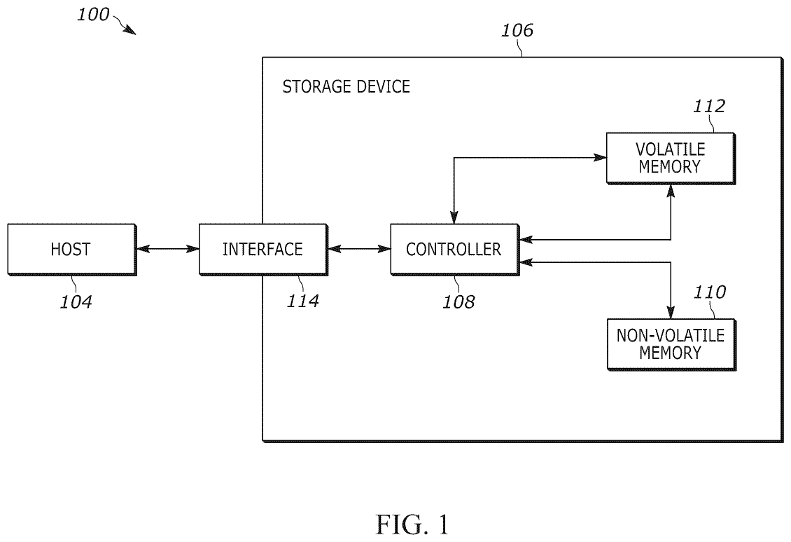

FIG. 1 is a block diagram illustrating a data storage system 100 with a storage device 106 that may function in conjunction with a host device 104, in accordance with one or more techniques of this disclosure. For instance, the host device 104 may utilize non-volatile memory devices included in storage device 106 to store and retrieve data.

The storage system 100 includes the host device 104 that may store and/or retrieve data to and/or from the storage device 106. As illustrated in FIG. 1, the host device 104 may communicate with the storage device 106 by way of an interface 114. The host device 104 may comprise any of a wide range of devices, including computer servers, network attached storage (NAS) units, desktop computers, notebook (i.e., laptop) computers, tablet computers, set-top boxes, telephone handsets such as so-called “smart” phones, so-called “smart” pads, televisions, cameras, display devices, digital media players, video gaming consoles, video streaming device, and the like.

As illustrated in FIG. 1, the storage device 106 includes a controller 108, non-volatile memory (NVM) 110, volatile memory 112, and an interface 114. In some examples, the storage device 106 may include additional components not shown in FIG. 1 for sake of clarity. For example, the storage device 106 may include a printed circuit board (PCB) to which components of the storage device 106 are mechanically attached and that includes electrically conductive traces that electrically interconnect components of the storage device 106, or the like. In some embodiments, the storage device 106 may include fewer components, for example, where one or more of the volatile memory 112 and the interface 114 are part of the controller 108. In some examples, the physical dimensions and connector configurations of the storage device 106 may conform to one or more standard form factors. Some example standard form factors of the storage device may include 3.5″ data storage device, 2.5″ data storage device, and 1.8″ data storage device. Some example standard form factors of the interface 114 may include peripheral component interconnect (PCI), PCI-extended (PCI-X), and PCI Express (PCIe) (e.g., PCIe x1, x4, x8, x16, PCIe Mini Card, MiniPCl, etc.). In some examples, the storage device 106 may be directly attached (e.g., directly soldered) to a motherboard of the host device 104.

The interface 114 of the storage device 106 may include one or both of a data bus for exchanging data with the host device 104 and a control bus for exchanging commands with the host device 104. The interface 114 may operate in accordance with any suitable protocol. For example, the interface 114 may operate in accordance with one or more of the following protocols: advanced technology attachment (ATA) (e.g., serial-ATA (SATA) and parallel-ATA (PATA)), Fibre Channel Protocol (FCP), small computer system interface (SCSI), serially attached SCSI (SAS), PCI, and PCIe, non-volatile memory express (NVMe), OpenCAPI, GenZ, Cache Coherent Interface Accelerator (CCIX), or the like. The interface 114 is communicatively connected (e.g., a data bus, a control bus, or other suitable connection) to the controller 108, allowing data to be exchanged between the host device 104 and the controller 108. In some examples, the interface 114 may also permit the storage device 106 to receive power from the host device 104.

The NVM 110 may be part of a packaged integrated circuit (IC) or other packaged silicon device, such as a stacked memory package. The NVM 110 may also include read/write circuitry that reads data from and writes data to another portion of the memory device. For instance, the read/write circuitry of the NVM 110 may receive data and a message from the controller 108 that instructs the read/write circuitry to store the data in the NVM 110. Similarly, the read/write circuitry of the NVM 110 may receive a message from the controller 108 that instructs the read/write circuitry to retrieve data from the NVM 110. In some examples, each die (i.e., the controller 108 and memory dies making up the NVM 110 of the memory device) may be individually referred to as a silicon die.

In some examples, the stacked memory packages may include any type of non-volatile memory. For example, the NVM 110 may include flash memory or any other suitable non-volatile memory. Flash memory may include NAND-based or NOR-based flash memory, and may store data based on a charge contained in a floating gate of a transistor for each flash memory cell. In NAND-based flash memory, the flash memory may be divided into a plurality of blocks that may divided into a plurality of pages. Each block of the plurality of blocks may include a plurality of NAND cells. Rows of NAND cells may be electrically connected using a word line to define a page of a plurality of pages. Respective cells in each of the plurality of pages may be electrically connected to respective bit lines. Furthermore, the NAND-based flash memory may be 2D or 3D, and may be configured as a single-level cell (SLC) memory, a multi-level cell (MLC) memory, a triple-level cell (TLC) memory, or a quad-level cell (QLC) memory.

The volatile memory 112 may be used by the controller 108 to store information. The volatile memory 112 may be comprised of one or more volatile memory devices. In some examples, the controller 108 may use the volatile memory 112 as a cache. For instance, the controller 108 may store cached information in the volatile memory 112 until the cached information is written to the NVM 110. Examples of the volatile memory 112 include, but are not limited to, random-access memory (RAM), dynamic random access memory (DRAM), static RAM (SRAM), and synchronous dynamic RAM (SDRAM (e.g., DDR1, DDR2, DDR3, DDR3L, LPDDR3, DDR4, LPDDR4, and the like)).

The controller 108 manages one or more operations of the storage device 106. For instance, the controller 108 manages the reading of data from and/or the writing of data to the NVM 110. In some embodiments, when the storage device 106 receives a write command from the host device 104, the controller 108 may initiate a data storage command to store data to the NVM 110 and monitor the progress of the data storage command. In other embodiments, the controller 108 may determine at least one operational characteristic of the storage system 100 and store the at least one operational characteristic in the NVM 110.

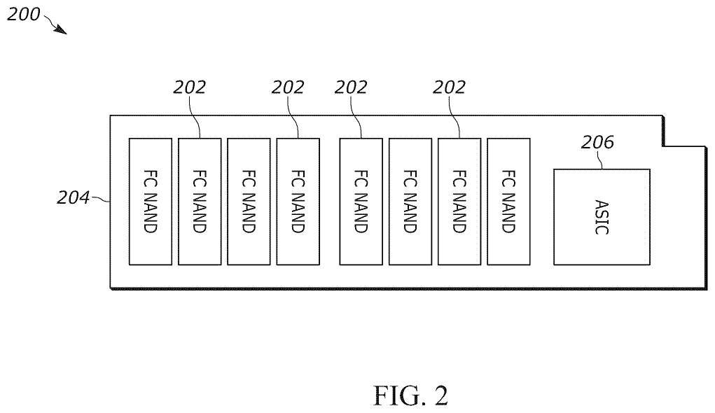

In some instances, the PCB of comparative SSD packages, such as M.2 2280 SSDs, allow for up to 8 flip chip NAND dies on the top side of the PCB, allowing for up to one terabyte (TB) of memory storage. As a comparative example, FIG. 2 is a diagram illustrating a PCB footprint 200 of a single-sided M.2 2280 SSD PCB. A plurality of flip chip (FC) NAND memory dies 202 are situated on a top portion of a PCB 204. An electronic processor 206 (for example, the controller 108) is also situated on the PCB 204. In the example of FIG. 2, the plurality of FC NAND memory dies 202 include eight memory dies providing 1 TB of memory storage. While examples described herein primarily illustrate an M.2 2280 SSD, embodiments described herein may also be implemented in other types of SSDs.

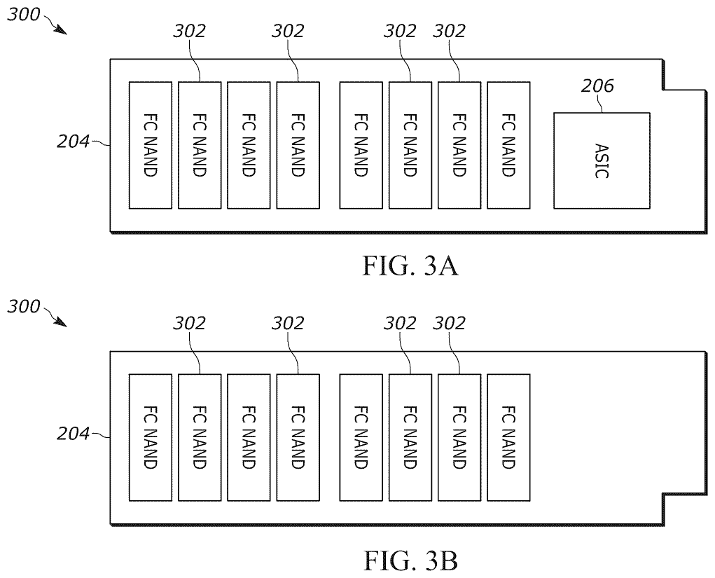

To increase storage capacity, in some instances, FC NAND memory dies are provided on both the top portion and the bottom portion of a PCB. As another comparative example, FIG. 3A is a diagram illustrating a first side of a PCB footprint 300 of a two-sided M.2 2280 SSD PCB. A first plurality of FC NAND memory dies 302 are situated on a top portion of the PCB 204 alongside the electronic processor 206. FIG. 3B is a diagram illustrating a second side of the PCB footprint 300 of a two-sided M.2 2280 SSD PCB. A second plurality of FC NAND memory dies 304 are situated on the bottom portion of the PCB 204. In the example of FIGS. 3A-3B, eight memory dies are provided on the top portion and eight memory dies are provided on the bottom portion, providing a total of 2 TB of memory storage.

While using the bottom portion of the SSD PCB provides for increased memory storage, additional PCB layers are also necessary to accommodate routing the memories dies on both sides of the SSD PCB. Examples described herein provide for packages, such as SSD memory packages, with stacked FC memory dies to achieve greater memory storage utilizing only one side of the SSD PCB.

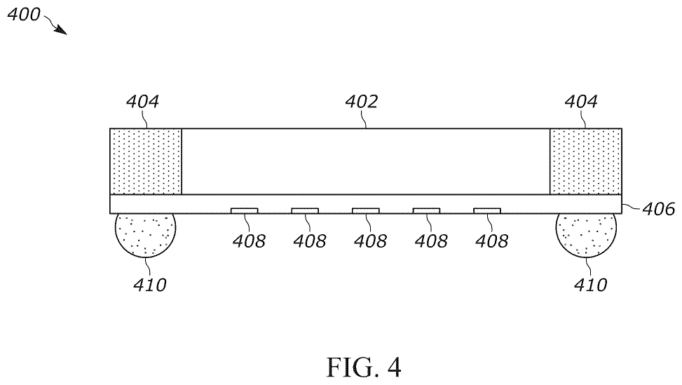

FIG. 4 is a diagram illustrating a first example of a first FC package 400 (for example, a FC NAND package). In some examples, the first FC package 400 is a fan out wafer level package (FO-WLP). The example first FC package 400 includes a memory die 402, a molded sidewall 404 (e.g., a molded support), a redistribution layer (RDL) 406, a plurality of metal pads 408, and interconnects 410. In the example of FIG. 4, the memory die 402 is an exposed die such that a top portion of the memory die 402 is exposed to air and adjacent to side portions of the memory die 402 contact the molded sidewall 404.

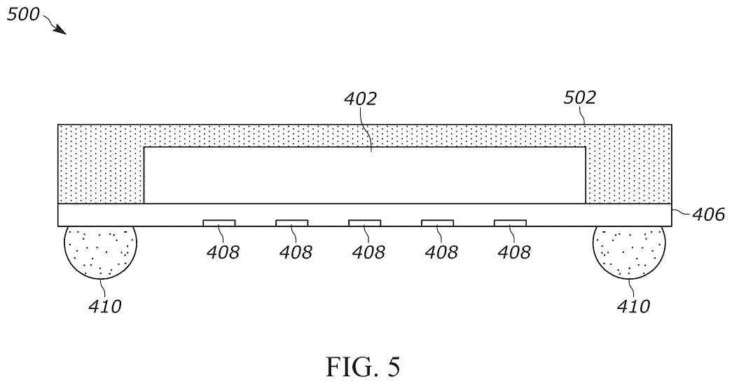

In some instances, the memory die 402 is fully covered by a molded encasement. For example, FIG. 5 is a diagram illustrating a second example of a first FC package 500 substantially similar to the first FC package 400 of FIG. 4. In the example first FC package 500, the memory die 402 is encased (e.g., covered) by a molded encasement 502 that is similar to the molded sidewall 404 of FIG. 4. The molded encasement 502 may be implemented by encapsulation of the memory die 402 with a plastic material, or may be implemented by covering the memory die 402 with a tape.

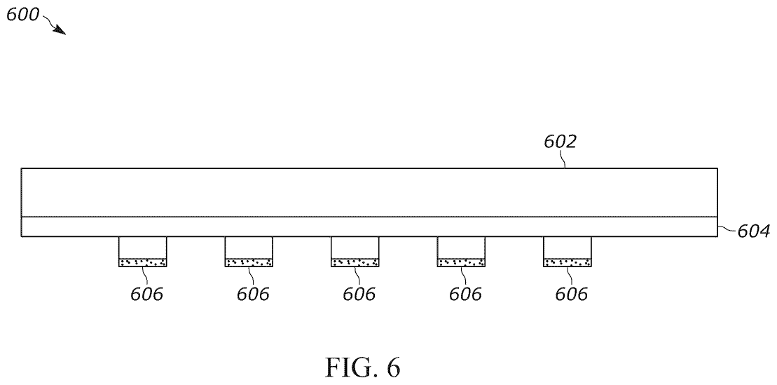

Returning to FIG. 4, the memory die 402 and the molded sidewall 404 are situated on a top portion of the RDL 406. The plurality of metal pads 408 are situated on (e.g., integrated or embedded into) a bottom portion of the RDL 406. The plurality of metal pads 408 may be composed of, for example, gold, silver, aluminum, copper, or some other conductive metal. The plurality of metal pads 408 are configured to receive corresponding interconnects 606 of a second FC package 600, as described with respect to FIG. 6. The interconnects 410 may be, for example, solder balls populated at a peripheral side of the first FC package 400. The interconnects 410 may connect the first FC package 400 to a PCB.

FIG. 6 is a diagram illustrates an example of a second FC package 600. In some examples, the second FC package 600 is a fan in wafer level package (FI-WLP). The example second FC package 600 includes a memory die 602, a RDL 604, and a plurality of interconnects 606. The memory die 602 is situated on an opposite side of the RDL 604 compared to the plurality of interconnects 606. The memory die 602 may be a similar type of memory package as the memory die 402. For example, the memory die 602 and the memory die 402 may be silicon dies of approximately the same size. In other instances, the memory die 602 and the memory die 402 may be different types of memory dies. For example, the memory die 602 may be physically smaller than the memory die 402. The plurality of interconnects 606 protrude (e.g., extend) from the RDL 604. The plurality of interconnects 606 may be composed of tin plated copper, may be a solder ball, may be a gold bump, may be a copper pillar, or the like.

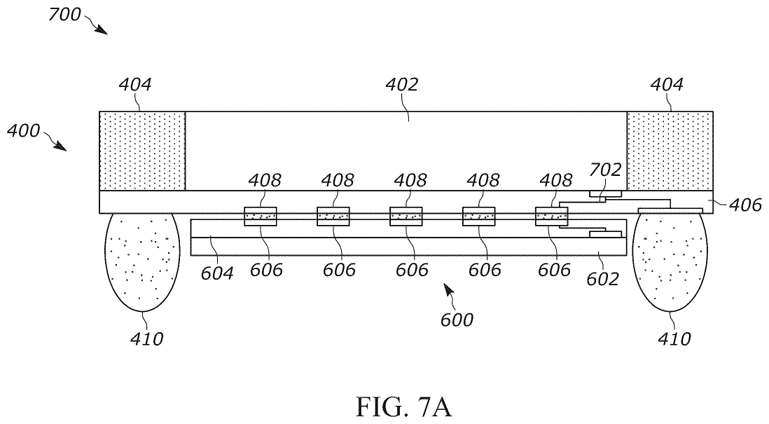

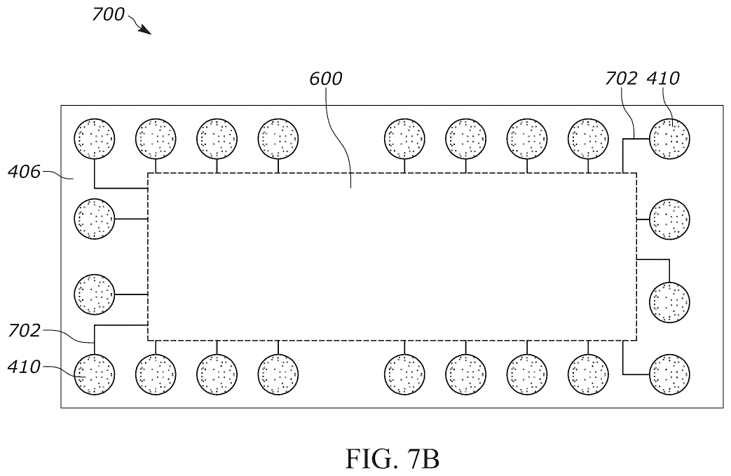

The second FC package 600 physically and electrically connects to the first FC package 400 to form a stacked FC package. For example, FIGS. 7A and 7B are diagrams illustrating an example of a stacked FC package 700. The stacked FC package 700 includes the second FC package 600 connected to the first FC package 400. In some implementations, the second FC package 600 is connected vertically below the first FC package 400. For example, a center of the first FC package 400 may align with a center of the second FC package 600. The plurality of interconnects 606 of the second FC package 600 are connected to the plurality of metal pads 408 of the first FC package 400. For example, the plurality of interconnects 606 may be soldered to the plurality of metal pads 408. In other examples, the plurality of interconnects 606 are connected to the plurality of metal pads 408 via an adhesive, such as an electrically conductive adhesive.

An electrical path 702 is provided between the first FC package 400 and the second FC package 600. In the example of FIGS. 7A and 7B, the electrical path 702 travels from the memory die 602, through the plurality of interconnects 606 and the plurality of metal pads 408, to the memory die 402, and through the interconnects 410. The interconnects 410 may then connect to a PCB, such as an SSD PCB on which the stacked FC package 700 is situated. Accordingly, signals are capable of traveling between the memory die 402 and the memory die 602 directly without interfacing through the PCB. The electrical path 702 may travel through the SSD PCB to connect to a controller, such as the controller 108 (not shown in FIGS. 7A and 7B).

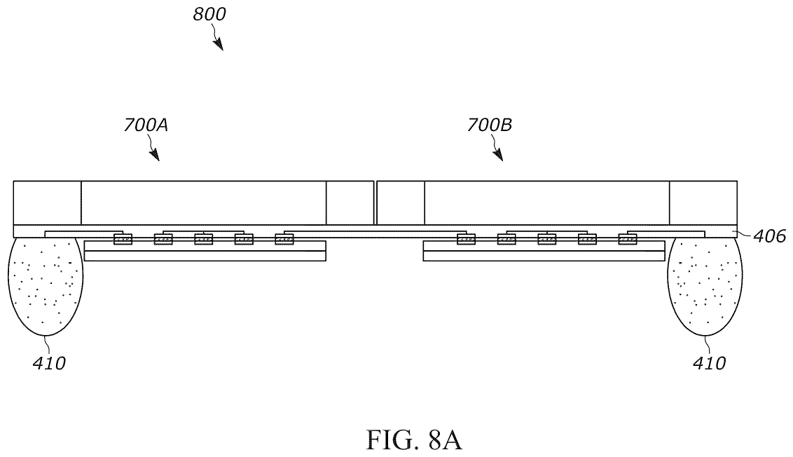

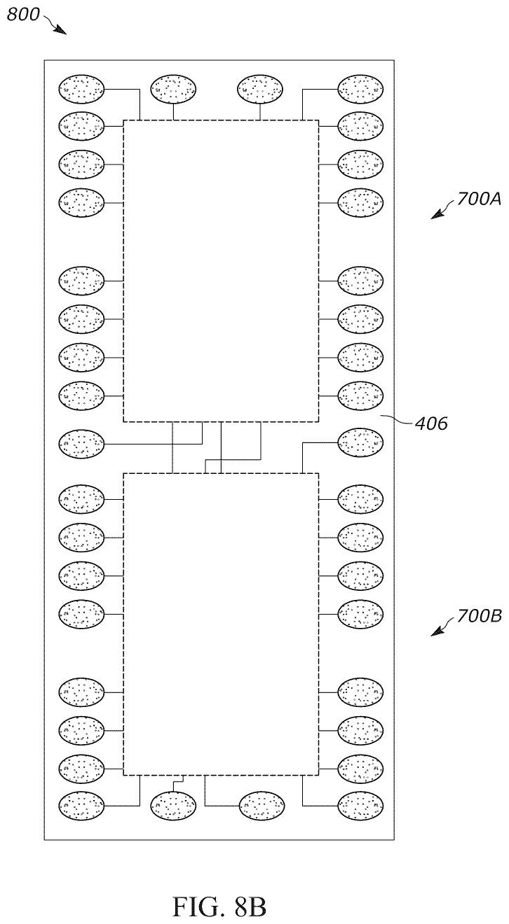

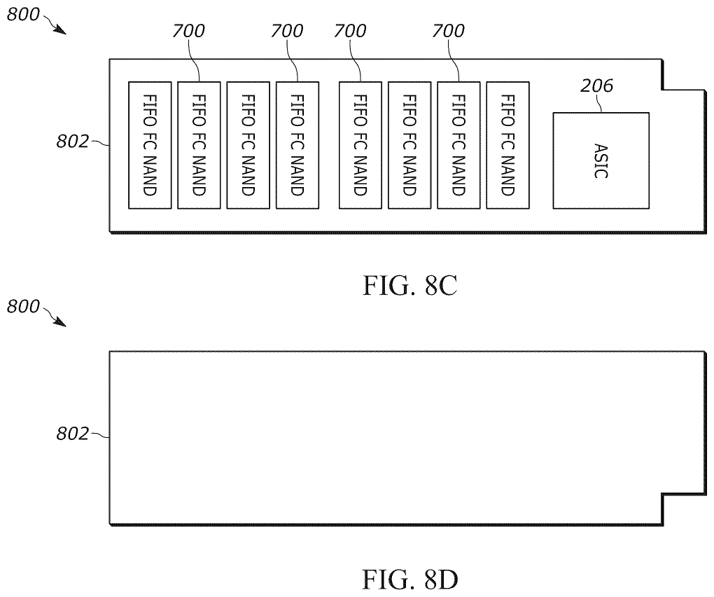

After the stacked FC package 700 is formed, multiple stacked memory packages 700 are placed onto an SSD PCB. For example, FIG. 8A is a diagram illustrating a cross-sectional view of a portion of an SSD PCB architecture 800. FIG. 8B is a bottom view of the SSD PCB architecture 800 of FIG. 8A. As shown in FIG. 8A, a first stacked FC package 700A and a second stacked FC package 700B are situated adjacent to each other as a combined package having a shared RDL 406. The first stacked FC package 700A and the second stacked FC package 700B may be two of a plurality of stacked FC packages 700, shown in FIG. 8C. For example, the interconnects 410 are soldered to the SSD PCB 802. In some examples, such as that illustrated in FIG. 8A, the first stacked FC package 700A and the second stacked FC package 700B contact one another. In other examples, the first stacked FC package 700A and the second stacked FC package 700B are separated from each other (e.g., by an air gap).

FIG. 8C is a diagram illustrating a plan view of the SSD PCB architecture 800. The plurality of stacked FC packages 700 are disposed on a first side (e.g., a top) of the SSD PCB 802 (alongside the electronic processor 206). FIG. 8D is a diagram illustrating a second side (e.g., a bottom) of the SSD PCB architecture 800 that is opposite to the first side. As seen in FIG. 8C, the second side of the SSD PCB 802 is empty.

In some instances, as shown in FIG. 8C, the plurality of stacked FC packages 700 are evenly spaced over the SSD PCB 802. In other instances, two or more of the plurality of stacked FC packages 700 may be connected together or disposed directly adjacent to each other.

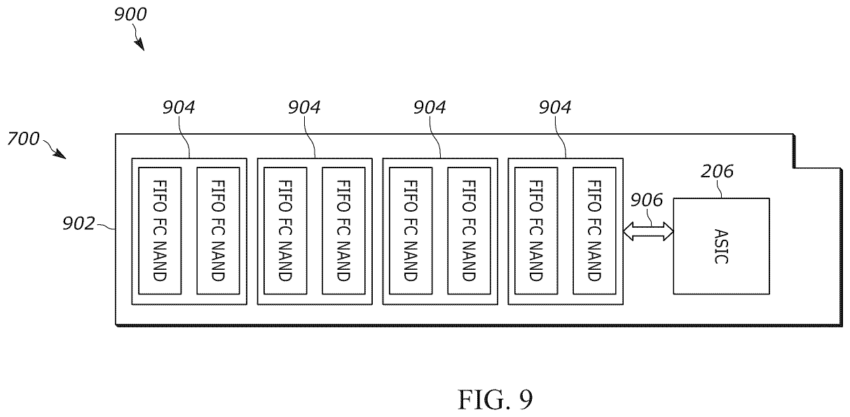

FIG. 9 is a diagram illustrating a second example of an SSD PCB architecture 900 that includes the plurality of stacked FC packages 700 on an SSD PCB 902. As shown in FIG. 9, the plurality of stacked FC packages 700 may be configured in pairs 904, where each stacked FC package 700 within the pair 904 is connected to one other stacked FC package 700. The paired configuration of the plurality of stacked FC packages 700 increases a distance 906 between the plurality of stacked FC packages 700 and the electronic processor 206, utilizing less area of the SSD PCB 902. In some implementations, rather than pairs 904 (e.g., a 1×2 matrix), the plurality of stacked FC packages 700 may be connected in triples (e.g., a 1×3 matrix), quadruples (e.g., a 1×4 matrix), or some other combination (e.g., up to a 1×N matrix).

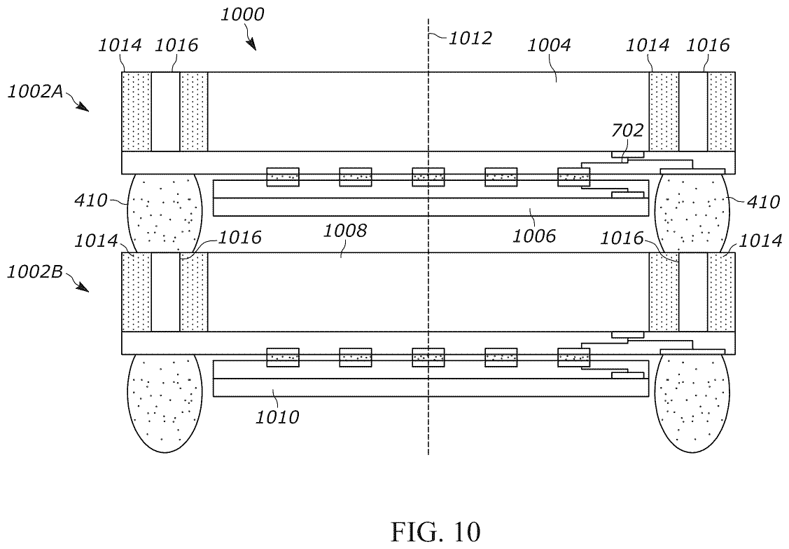

Additionally, in some implementations, the stacked FC packages may be further stacked upon one another, creating a tower of memory dies. FIG. 10 is a diagram illustrating a cross-sectional view of a FC memory die tower 1000 including a first stacked FC package 1002A connected to a top portion of a second stacked FC package 1002B. The first stacked FC package 1002A includes a first memory die 1004 and a second memory die 1006. The second stacked FC package 1002B includes a third memory die 1008 and a fourth memory die 1010. The interconnects 410 of the first stacked FC package 1002A may be connected to the molded sidewall 1014 of the second stacked FC package 1002B. The first stacked FC package 1002A and the second stacked FC package 1002B may be stacked such that the first memory die 1004, the second memory die 1006, the third memory die 1008, and the fourth memory die 1010 are situated along a same axis 1012.

To enable communication between the first stacked FC package 1002A and the second stacked FC package 1002B, the molded sidewall 1014 may include a metal interconnect 1016, such as a through via. The metal interconnect 1016 may connect to the electrical path 702 and the interconnects 410, electrically connecting the first stacked FC package 1002A and the second stacked FC package 1002B.

In some implementations, the stacked FC packages are both (i) further stacked into a tower (as shown in FIG. 10) and (ii) connected to an adjacent stacked FC package (as previously shown in FIG. 9). In this manner, the plurality of stacked FC packages may be connected in an M×N matrix instead of a 1×N matrix.

While examples described herein primarily refer to memory dies, the packages described herein may also be utilized for other types of dies. For example, controller dies may be implemented within packages described herein.

While the foregoing is directed to embodiments of the present disclosure, other and further embodiments of the disclosure may be devised without departing from the basic scope thereof. The scope of the present disclosure should be determined by the following claims.

What is claimed is:

1. A package comprising:
a first flip chip package comprising:
a first memory die,
a metal pad, and
a redistribution layer, wherein the first memory die is connected to a first side of the redistribution layer, and wherein the metal pad is integrated into a second side of the redistribution layer; and
a second flip chip package vertically stacked on the first flip chip package, the second flip chip package comprising:
a second memory die, and
an interconnect configured to contact the metal pad,
wherein a center of the first memory die is aligned with a center of the second memory die.

2. The package of claim 1, wherein the second memory die is smaller than the first memory die.

3. The package of claim 1, wherein the first flip chip package further includes a molded support configured to contact a side portion of the first memory die.

4. The package of claim 1, further comprising:
a third flip chip package comprising:
a third die, and
a second metal pad; and
a fourth flip chip package vertically stacked on the third flip chip package, the fourth flip chip package comprising:
a fourth die, and
a second interconnect configured to contact the second metal pad.

5. The package of claim 4, wherein the third die is a first controller die, and wherein the fourth die is a second controller die.

6. The package of claim 1, wherein the second flip chip package further includes a redistribution layer, wherein the second die is connected to a first side of the redistribution layer, and wherein the interconnect is connected to a second side of the redistribution layer.

7. The package of claim 1, wherein the first memory die is electrically connected to the second die by an electrical path, wherein the electrical path travels through the metal pad and the interconnect.

8. The package of claim 7, wherein the first flip chip package is connected to a printed circuit board, and wherein the electrical path travels from the first memory die to the printed circuit board.

9. A package comprising:
a first vertically stacked package including:
a first memory die electrically and physically coupled to a second memory die, and
a first sidewall surrounding at least a portion of the first memory die; and
a second vertically stacked package including:
a third memory die electrically and physically coupled to a fourth memory die, and
a second sidewall surrounding at least a portion of the third memory die,
wherein first sidewall contacts the second sidewall.

10. The package of claim 9, wherein the first stacked package further includes a first redistribution layer supporting the first memory die, and wherein the second stacked package further includes a second redistribution layer supporting the third memory die.

11. The package of claim 10, wherein the first redistribution layer contacts the second redistribution layer.

12. The package of claim 9, further comprising:
a third stacked package including:
a fifth memory die electrically and physically coupled to a sixth memory die, and
a third sidewall surrounding at least a portion of the fifth memory die,
wherein the second sidewall contacts the third sidewall.

13. The package of claim 9, wherein the first sidewall is a sidewall of a molded encasement, and wherein the molded encasement encloses the first memory die.

14. A package comprising:
a first stacked package including:
a first memory die electrically and physically coupled to a second memory die, and
a second stacked package coupled to a top portion of the first stacked package, the second stacked package including:
a third memory die electrically and physically coupled to a fourth memory die,
wherein the first memory die, the second memory die, the third memory die, and the fourth memory die are vertically aligned on a same axis.

15. The package of claim 14, wherein the first stacked package includes a first molded sidewall surrounding a at least a portion of the first memory die, and wherein the second stacked package includes a second molded sidewall surrounding at least a portion of the second memory die.

16. The package of claim 15, wherein the first molded sidewall includes a first through electrically coupling the first stacked package to the second stacked package.

17. The package of claim 15, wherein the first stacked package includes an interconnect situated between the first molded sidewall and the second molded sidewall.

18. The package of claim 14, wherein the first memory die and the second memory die are electrically and physically connected by a plurality of interconnects.

19. The package of claim 18, wherein the second memory die is situated on a redistribution layer, and wherein the plurality of interconnects protrude from the redistribution layer.

20. The package of claim 14, wherein the second stacked package is connected to a printed circuit board of an M.2 2280 SSD.
